(19) United States
(12) Patent Application Publication
(10) Pub. No.: US 2011/0136265 A1
(43) Pub. Date: Jun. 9, 2011

(54) Method of Manufacturing Thin-Film Solar Panel and Laser Scribing Apparatus

(75) Inventors: Keigo SHIGENOBU, Ebina-shi (JP); Hiroshi HONDA, Ebina-shi (JP); Yasuhiko KANAYA, Ebina-shi (JP)

(73) Assignee: Hitachi Via Mechanics, Ltd., Ebina-shi (JP)

(21) Appl. No.: 12/962,212

(22) Filed: Dec. 7, 2010

(30) Foreign Application Priority Data
Dec. 8, 2009 (JP) 2009-278921
Aug. 5, 2010 (JP) 2010-175878

(51) Int. Cl. H01L 21/66; B23K 26/00

(52) U.S. Cl. 438/4; 219/121.67; 257/E21.53

(57) ABSTRACT

The present invention provides a method of manufacturing a thin-film solar panel with a laser scribing process to perform linear groove processing by irradiating a thin-film layer formed on a substrate with laser light to be separated from adjacent structure, including steps of: specifying an accurate position, size, shape of a adhered foreign matter on a glass substrate, a glass scratch, an air-bubble in the glass substrate causing an imperfection by inspecting a scribe line; and performing repair processing to form a new scribe line to bypass a portion of the imperfection after a final scribe line is formed.

### BACKGROUND OF THE INVENTION

1. Field of the Invention

The present invention relates to a laser scribing technology in a manufacturing process of a thin-film solar panel.

2. Description of the Related Art

Recently, solar panels are being extensively developed. FIG. 10 illustrates a processed example with a scribing apparatus of a single-type amorphous silicon thin-film solar panel which is generally known and mass-produced by a number of manufacturers of solar panels. FIG. 11 is an enlarged fragmentary sectional view taken along the line A-A in FIG. 10. After a transparent electrode layer 3 is formed on a glass substrate 1, scribe lines 6 are scribed to form line-shaped grooves by a laser and the like in order to separate from an adjacent cell. Then, after an amorphous silicon layer 4 is formed thereon, scribe lines 7 are similarly scribed for separation. Further, after a back-side electrode layer 5 is formed thereon, scribe lines 8 are similarly scribed for separation. Normally, the distance between adjacent scribe line groups 2 is 6 to 12 mm, the distance between adjacent scribe lines is 100 to 150 μm, and the width of each scribe line is approximately 40 to 70 μm.

First, an example of a laser beam machine (i.e., a laser scribing apparatus) to perform such scribing is illustrated in FIGS. 12 to 14. FIG. 12 is a plan view of the laser scribing apparatus and FIG. 13 is a front view thereof. FIG. 14 is an operational flowchart. In the case of this scribing apparatus, a dust collector 109 is arranged right above a position of the glass substrate 1 to be irradiated with laser light through a condenser lens 108 so as to be configured to be capable of removing powder dust and the like generated by laser scribing.

As the first process of the scribing of a thin-film solar panel with the laser scribing apparatus, the glass substrate 1 on which the transparent electrode layer 3 is formed as illustrated in FIG. 11 is supplied on a conveying surface 102 of a laser scribing apparatus main body 100. Here, in the present embodiment, a face of the glass substrate 1 not having the transparent electrode layer 3 formed is directed to the conveying surface 102 and the transparent electrode layer 3 is directed upward. Forming of the transparent electrode layer 3 can be performed with a known method such as a sputtering method, a CVD method or a vapor deposition method. As a method of supplying on the conveying surface 102, the glass substrate 1 is supplied from a conveying loader portion in the case that the present apparatus is connected to an upstream apparatus via the conveying loader portion in a factory production line. In the case of not being connected via the conveying loader, the supplying may be performed by a conveying robot or the like. The glass substrate 1 supplied on the glass substrate conveying surface 102 is chucked by a glass substrate hold portion 104 which is attached to a conveyance drive portion 103. The glass substrate 1 reciprocates on the conveying surface 102 along with reciprocating of the conveyance drive portion 103 on a conveyance drive portion guide 105. The conveying surface 102 is constituted so as not to damage the glass substrate 1, such as an air floating table or a table with resin-made free rollers.

The glass substrate 1 is irradiated with laser light 110 deflected by reflection mirrors (i.e., a pair of galvanometer mirrors) 107 and through a condenser lens (i.e., an fθ lens) 108, in a synchronized manner with the reciprocating motion of the glass substrate 1 on the conveying surface 102 so as to form scribe lines 111. Dust is generated due to evaporation of the transparent electrode layer 3 at a position irradiated with the laser light 110 by the processing with the laser light 110. The dust is collected by the dust collector 109. Here, the reflection mirror 107 and the condenser lens 108 are arranged on a movable table 106. Then, a predetermined number of lines are formed by sequential movement from a position for a scribe line formed to a position for the next scribe line to be formed, synchronized with the leftward and rightward motions of the glass substrate 1.

The above operation will be described with reference to a flowchart of FIG. 14. The glass substrate 1 is conveyed and supplied on the conveying surface 102. The glass substrate 1 supplied on the conveying surface 102 is chucked by the glass substrate hold portion 104 so as to be in a state of being capable of reciprocating on the conveying surface 102. When the processing is started with an operator's instruction or the like, the movable table 106 having the reflection mirrors 107 and the condenser lens 108 (hereinafter, referred to collectively as “a processing head”) is moved to the position for processing the first scribe line and N is set to be one as the first line (step 301). Then, the glass substrate 1 is conveyed for leftward processing (step 302) and the leftward processing (for the first line) is performed as the glass substrate 1 passes above the laser light irradiation position at predetermined set speed (step 303). After the first scribe line is formed with the leftward processing, the glass substrate 1 stops moving on the conveying surface 102 and the movable table 106 is moved to the position for processing the next scribe line (step 304). Here, after checking whether or not being the final scribe line (step 305), the glass substrate 1 is conveyed back for return processing (step 306). Then, the return processing (for the second line as being N+1) is performed as the glass substrate 1 passes above the laser light irradiation position at the predetermined set speed (step 307) and the glass substrate 1 stops (step 308). Subsequently, processes of the leftward processing (for lines of N=3, 5, 7, . . . ) and the return processing (for lines of N+1=4, 6, 8, . . . ) are repeated until forming the final scribe line (steps 302 to 310). The operation ends when processing of the predetermined number of lines set by a program is completed. The above operation is described in the case of one processing head. In the case of a plural processing heads, the processing heads perform processing simultaneously in their respective assigned areas. The operation ends when processing of a predetermined number of lines for each processing head is completed.

After the scribe lines 6 of the transparent electrode layer 3 as illustrated in FIG. 11 are formed in the first process, the glass substrate 1 having the amorphous silicon layer 4 formed on the transparent electrode layer 3 is supplied on the conveying surface 102 of the laser scribing apparatus main body 100 as the second process. Here, in the present embodiment, a face of the glass substrate 1 not having the transparent electrode layer 3 and the amorphous silicon layer 4 formed is directed to the conveying surface 102. That is, the transparent electrode layer 3 and the amorphous silicon layer 4 are directed upward. The scribe lines 7 are formed in the amorphous silicon layer 4 at positions not overlapping with the scribe lines 6 formed in the first process. The processing method is similar to that in the first process.

After the scribe lines 7 of the amorphous silicon layer 4 are formed in the second process, the glass substrate 1 having the back-side electrode layer 5 formed on the amorphous silicon layer 4 is supplied on the conveying surface 102 of the laser scribing apparatus main body 100 as the third process. Here, in the present embodiment, a face of the glass substrate 1 not having the transparent electrode layer 3, the amorphous silicon layer 4 and the back-side electrode layer 5 formed is directed to the conveying surface 2. That is, the transparent electrode layer 3, the amorphous silicon layer 4 and the back-side electrode layer 5 are directed upward. The scribe lines 8 are formed in the amorphous silicon layer 4 and the back-side electrode layer 5 at positions not overlapping with the scribe lines 6, 7 formed in the first and second processes. The processing method is similar to that in the first process.

FIG. 15 being an enlarged fragmentary view taken within the circle B of a scribe line group 2 in FIG. 10 illustrates scribe lines 6 to 8 formed with the above method. Circles in FIG. 15 indicate laser spots (φ50 μm) used for the processing. During the formation process, there may be created a processing imperfection (hereinafter, referred to simply as “an imperfection”) that a scribe line is discontinued at some intermediate point where there exists a glass scratch 9, a foreign matter 10 adhered to the substrate which cannot be removed in a cleaning process performed in an upstream process on the film formed side or the back side of the glass substrate 1, or an air-bubble 15 in the glass substrate as illustrated in FIGS. 16 and 17, or the like. A scribe line 6b indicates an example of an imperfection of discontinuation in the transparent electrode layer 3 at which the laser processing is hindered by the adhered foreign matter 10. A scribe line 8b indicates an example of an imperfection of discontinuation in the amorphous silicon layer 4 and the back-side electrode layer 5 at which the laser processing is hindered by the glass scratch 9.

In the case that an imperfection exists in a scribe line 6 formed in the transparent electrode layer 3 as described above, adjacent photovoltaic portions 11, 12 are connected electrically as illustrated in FIG. 18 resulting in that photovoltaic efficiency is decreased. Further, also in the case that an imperfection exists in the scribe line 8 formed in the amorphous silicon layer 4 and the back-side electrode layer 5, adjacent photovoltaic portions 13, 14 are connected electrically as illustrated in FIG. 19 resulting in that photovoltaic efficiency is decreased. Here, the scribe line 7 formed only in the amorphous silicon layer 4 is to function as a passage for electrons from the back-side electrode layer 5 to the transparent electrode layer 3. Accordingly, even when discontinuation occurs at some intermediate point due to a glass scratch 9, an adhered foreign matter 10, an air-bubble15 in the glass substrate, or the like, electrons bypass through a portion which is normally scribed. Therefore, the influence to the decrease of photovoltaic efficiency is extremely small as being negligible compared to that in the scribe lines 6, 8.

For such an imperfection (i.e., a defect), Japanese Patent Application Laid-Open No. 2004-214565 discloses in paragraphs 0033-0034 a method to detect an imperfection portion with a microscope after performing scribe line processing and to repair by removing the portion with emitting an impelled mixture of ice and water onto the imperfect portion.

Further, Japanese Patent Application Laid-Open No. 2009-195968 discloses a method to detect an imperfect portion by detecting transmitted laser light and measuring electric characteristics and to repair by re-performing the laser processing after performing removal of foreign matters from the detected portion with a second laser light source or performing removal with an air knife or a brush, at paragraphs 0029, 0035 and 0047 for imperfection detecting and paragraph 0039 to 0040, 0055 and 0058 for imperfection removal and repair processing.

Further, Japanese Patent Application Laid-Open No. 2010-021517 discloses an inspection and repair method for a thin-film solar cell unit (photovoltaic portion) which a short-circuit is detected between the adjacent thin-film solar cell unit based on the resistance value measurement using probes, by scribing one or more new (linear) laser scribe lines for the unit by moving the glass substrate at a predetermined distance repeatedly until the short-circuit is not detected, at paragraphs 0039 to 0062 as the second and third embodiments.

Regarding a viewpoint of imperfection inspection of a glass substrate, there has been an inspection method to detect the position of an imperfection in the direction of thickness of the glass substrate based on an illumination gradient index value calculated by processing an image of the imperfection in the glass substrate captured by a camera, as disclosed in Japanese Patent Application Laid-Open No. 2004-361384 at paragraphs 0013 to 0040.

With the method of Japanese Patent Application Laid-Open No. 2004-214565, imperfect portions are to be detected manually using the microscope after performing the scribe line processing. Here, since every separation groove (scribe line) has to be inspected, it takes much time to detect all imperfect portions. In addition, there has been a problem that the other normal portions are being damaged when removing the imperfect portions by emitting an impelled mixture of ice and water to the imperfect portions.

Further, with the method of Japanese Patent Application Laid-Open No. 2009-195968, although detection of imperfect portions can be performed simultaneously with the laser scribing, the apparatus therefor becomes extensive since the laser scribing is performed again after removing foreign matters from the imperfect portions with the second laser light source, the air knife, or the brush. Further, since transmitted light is used for the imperfection detection, it is difficult to detect an imperfection in the transparent electrode layer or the amorphous silicon layer, Ibid. paragraph 0031. In addition, there has been a problem that repair cannot be performed, because it is impossible to remove an imperfection caused by a scratch 9, an air-bubble 15, or the like in the glass substrate 1 illustrated in FIGS. 16 and 17, which are not adhered thereto.

Further, with the method of Japanese Patent Application Laid-Open No. 2010-021517, since one or more (linear) scribe lines for a solar cell unit are repeatedly scribed until short-circuit is not detected by moving the glass substrate at a predetermined distance a when short-circuit exists, the processing time is to be prolonged.

With the method of Japanese Patent Application Laid-Open No. 2004-361384, the inspection takes time since the whole glass substrate must be scanned including in the direction of the thickness for specifying imperfect portions.

### SUMMARY OF THE INVENTION

The present invention provides a method capable of repairing every imperfection easily and reliably by specifying the accurate position, size, shape of a scratch in the glass substrate 1 or the like causing the imperfection.

To address the above issues, according to the present invention, an additional laser scribing is performed to bypass an imperfection portion after specifying the accurate position, size, shape of a scratch, or the like causing the imperfection, by inspecting scribe lines using a resistance tester and inspection cameras.

Further, by shifting a focal point from a film formed side to a glass face side as changing the distance between the inspection camera and the glass substrate, it becomes possible to detect even an air-bubble or the like within the glass substrate.

It is known that the sensitivity for an imperfection of an inspection camera by detecting a reflection light under epi-illumination is better than that by detecting a transmitted light. In addition, by an additional scribing to bypass the imperfect portion due to a foreign matter adhered to the glass substrate, an air-bubble therein, or the like, a reliable repair can be performed for every imperfection.

In amorphous silicon thin-film solar panels, the thickness of the glass substrate is generally in a range of 2 to 4 mm. Therefore, in inspecting scribe lines formed in films with an inspection camera, when discontinuation of a scribe line is caused by a scratch existing in a glass face side (the opposite side to a film formed side), the position, size and shape of the scratch or the like cannot be accurately viewed due to the focal depth of the camera (normally, being in the order of μm).

According to the present invention, a repair processing of an additional scribing to bypass an imperfect portion can be reliably performed with the same apparatus by specifying the accurate position, size, shape of the glass scratch 9, the adhered foreign matter 10, the air-bubble 15, or the like causing the imperfection, while the decrease of photovoltaic efficiency is suppressed to the minimum.

### BRIEF DESCRIPTION OF THE DRAWINGS

FIG. 1 is a plane view of a laser scribing apparatus according to apparatus example 1 of the present invention;

FIG. 2 is a side view of the laser scribing apparatus according to apparatus example 1 of the present invention;

FIG. 3 is an operational flowchart of laser scribing processing according to apparatus example 1 of the present invention;

FIG. 4 is a plane view of a laser scribing apparatus according to apparatus example 2 of the present invention;

FIG. 5 is a side view of the laser scribing apparatus according to apparatus example 2 of the present invention;

FIG. 6 is an operational flowchart of laser scribing processing according to apparatus example 2 of the present invention;

FIG. 7 is the first repair processing example with the laser scribing processing according to the present invention;

FIG. 8 is the second repair processing example with the laser scribing processing according to the present invention;

FIG. 9 is the third repair processing example with the laser scribing processing according to the present invention;

FIG. 10 is an example of a thin-film solar panel to which laser scribing is performed;

FIG. 11 is an enlarged fragmentary sectional view taken along the line A-A of FIG. 10;

FIG. 12 is a plane view of a laser scribing apparatus in the related art;

FIG. 13 is a side view of a laser scribing apparatus in the related art;

FIG. 14 is an operational flowchart of laser scribing processing in the related art;

FIG. 15 is an enlarged fragmentary view taken within the circle B of FIG. 10;

FIG. 16 illustrates an example of imperfect portions;

FIG. 17 is a sectional view illustrating positional relation between a glass substrate and an inspection camera;

FIG. 18 is a sectional view of a case that a imperfection occurs in a transparent electrode layer 3; and

FIG. 19 is a sectional view of a case that a imperfection occurs in a back-side electrode layer 5.

### DESCRIPTION OF THE PREFERRED EMBODIMENTS

In the following, apparatuses and methods therewith for specifying imperfect positions preferable for the present invention will be described as apparatus example 1 and apparatus example 2, and then, repair methods will be described as processing example 1, processing example 2 and processing example 3.

### APPARATUS EXAMPLE 1

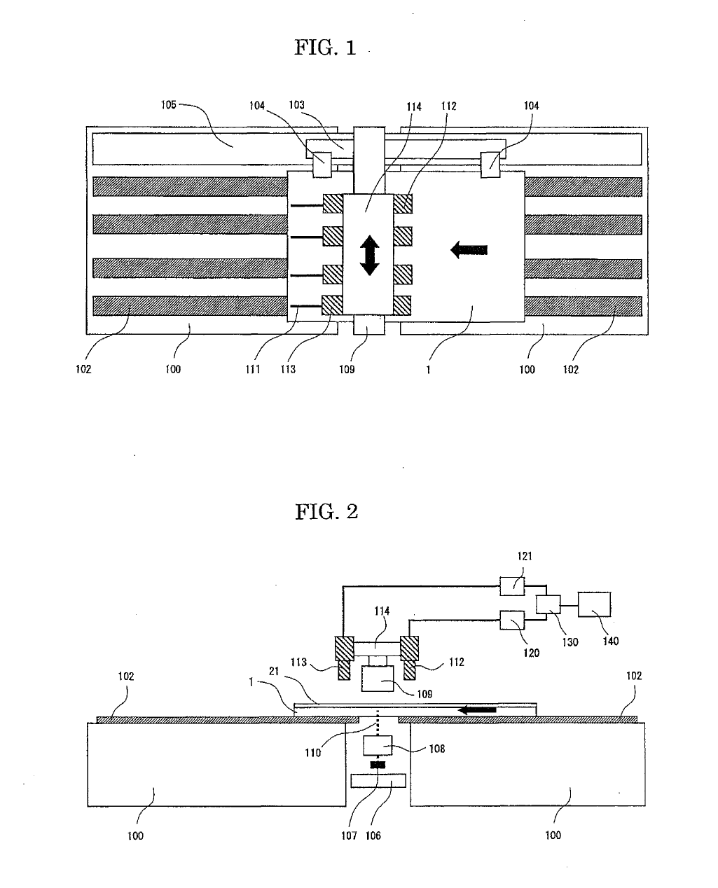

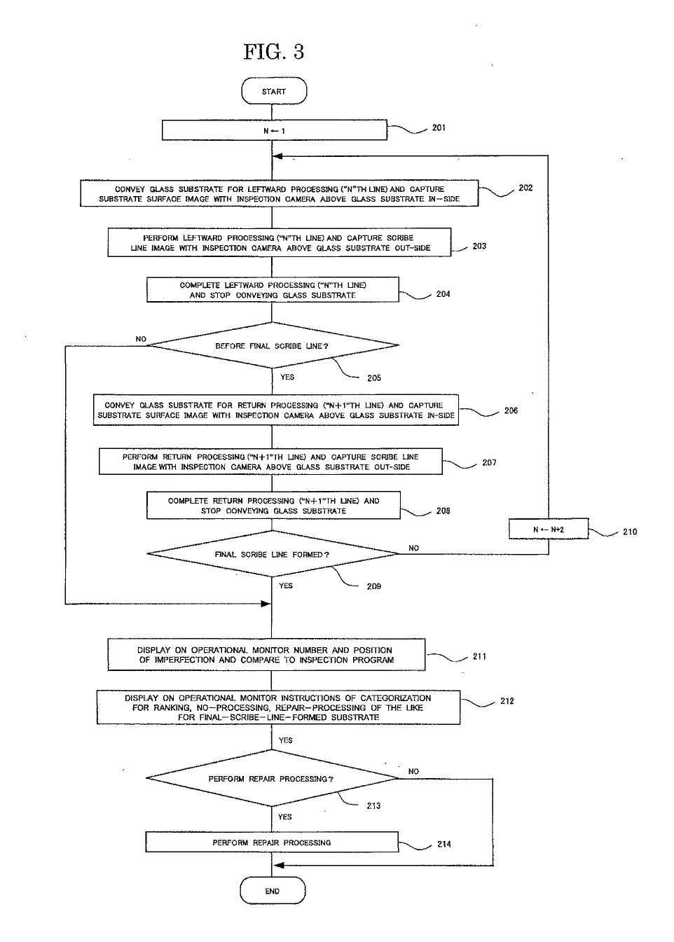

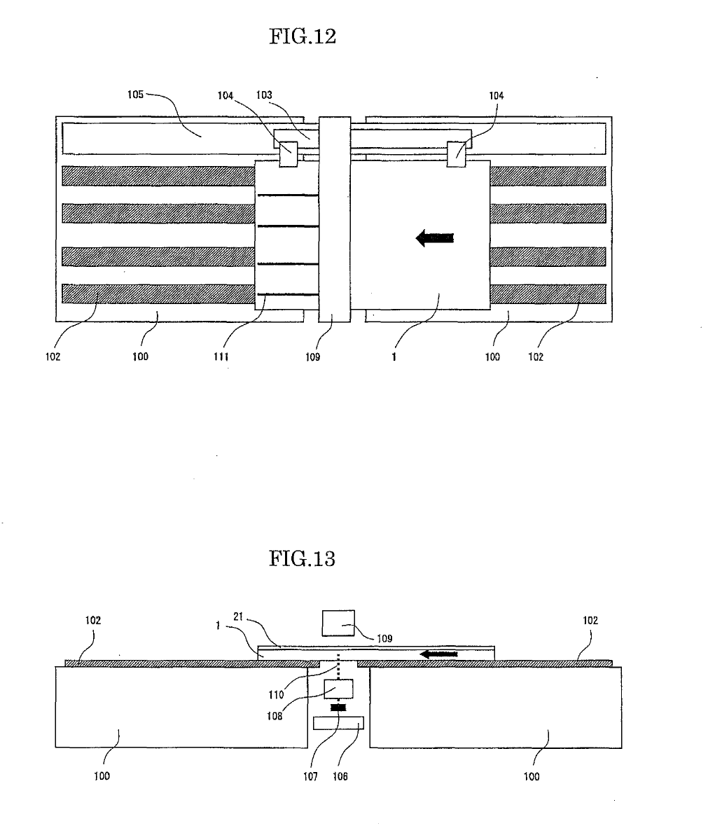

FIGS. 1 and 2 illustrate a laser scribing apparatus preferable for a laser describing method according to apparatus example 1 of the present invention. FIG. 1 is a plan view and FIG. 2 is a front view. The same numeral is given to the similar element of an apparatus in the related art of FIGS. 12 and 13 and description thereof will not be repeated.

A laser scribing apparatus of apparatus example 1 of the present invention is provided with inspection cameras 112, 113 disposed respectively right before and right after of the processing head. Two or more inspection cameras 112, 113 are fixed respectively on both sides of a camera table 114 movable in the direction (i.e, the direction of a vertical arrow in FIG. 1) perpendicular to the substrate conveying direction (i.e., the direction of a leftward arrow in FIG. 1) as being synchronized with the movable table 106 to which the condenser lens 108 is disposed. The substrate surface image can be captured right before and right after the scribing with the processing head by the inspection cameras 112, 113. The inspection cameras 112, 113 are each provided with an epi-illumination device (not illustrated) of a coaxial type or an oblique type such as ring-shaped illumination.

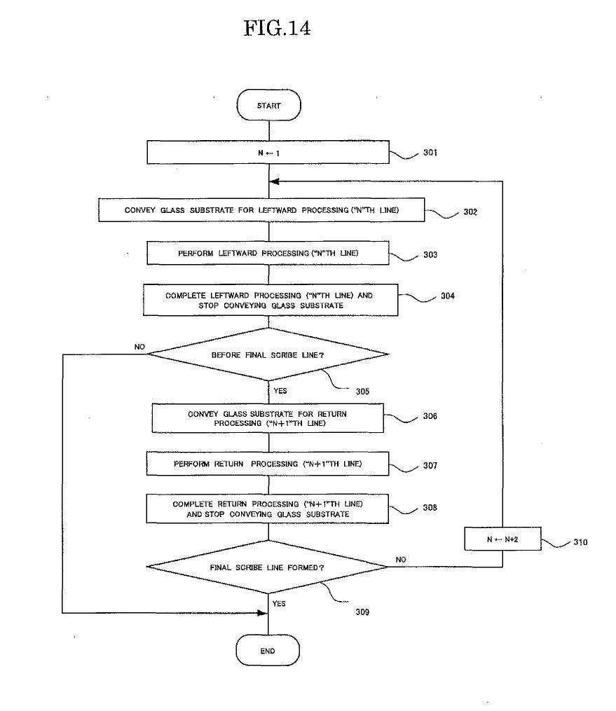

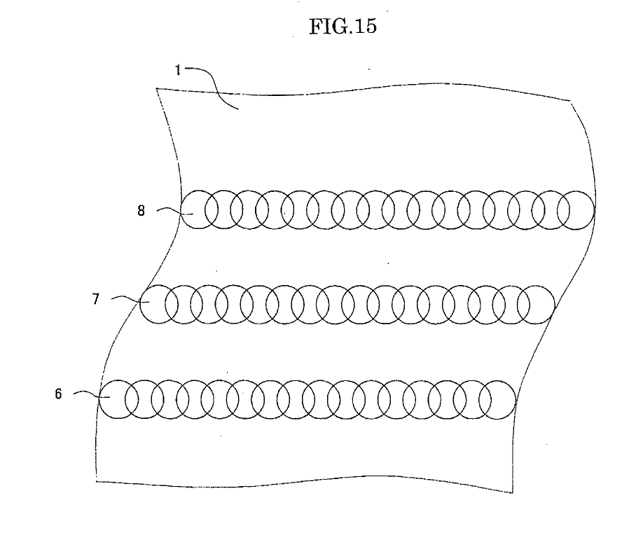

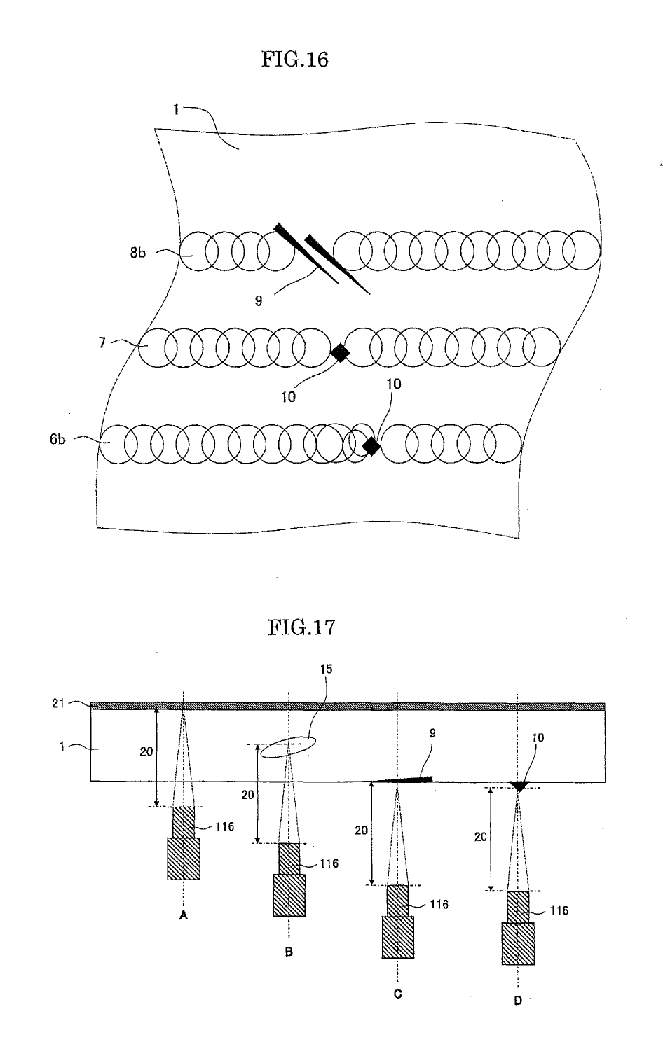

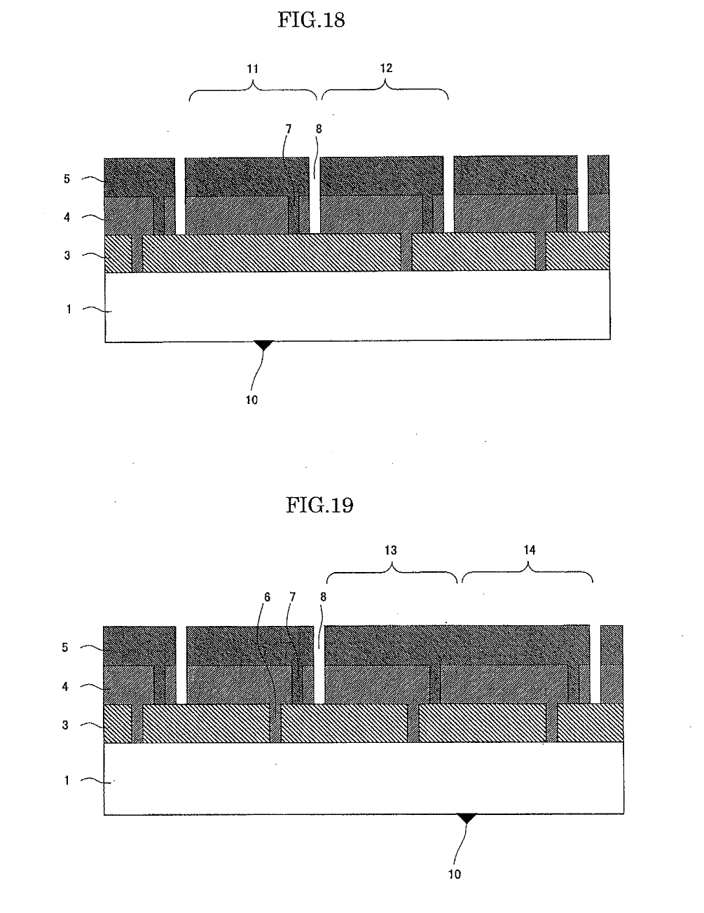

The operation of the laser scribing apparatus of apparatus example 1 of the present invention will be described with reference to a flowchart of FIG. 3. Steps 201 to 210 are approximately similar to those in the flowchart of the related art described in FIG. 14. The glass substrate 1 on which a transparent electrode layer 3, or additionally an amorphous silicon layer 4 and a back-side electrode layer 5 (hereinafter, referred to collectively as “a film-formed layer” 21) is formed is conveyed and supplied on the conveying surface 102. In this processing apparatus, a dust collector 109 is arranged right above a position of the glass substrate 1 irradiated with laser light through a condenser lens 108 so as to remove powder dust and the like generated by the laser processing. The glass substrate 1 supplied to the conveying surface 102 is chucked by the glass substrate hold portion 104 so as to be reciprocated on the conveying surface 102. When the processing is started with an operator's instruction or the like, the movable table 106 having the processing head mounted and the camera table 114 are moved to a position for the first scribe line and N is set to be one as the first line (step 201). The glass substrate 1 is conveyed for leftward processing and the surface image thereof is captured by the inspection camera 112 (i.e., IN-side) right before entering the processing head portion, and then, the image data is recorded in an image processing and recording device 120 (step 202). The leftward processing (for the first line) is performed as the glass substrate 1 passes above the laser light irradiation position (i.e., the processing head) at a predetermined set speed, and then, the surface image thereof (i.e., the result of the processing) is captured by the inspection camera 113 (i.e., OUT-side) right thereafter. After being recorded in an image processing and recording device 121, the image data thereof is compared to the image data at the same portion recorded in the image processing and recording device 120 at an arithmetic device 130. When an imperfection exists, the imperfect portion thereof is recorded in an imperfect portion recording device 140 (step 203). After the first scribe line is formed with the leftward processing, the glass substrate 1 stops moving on the conveying surface 102 and the movable table 106 and the camera table 114 are moved to the position for the next scribe line (step 204). Here, after checking whether or not being the final scribe line (step 205), the glass substrate 1 is conveyed for return processing and the surface image thereof is captured by the inspection camera 113 (i.e., IN-side this time) right before entering the processing head portion, and then, the image data is recorded in the image processing and recording device 121 (step 206). The return processing (for the second line as being N+1) is performed as the glass substrate 1 passes above the laser light irradiation position at the predetermined set speed, and then, the surface image thereof (i.e., the result of the processing) is captured by the inspection camera 112 (i.e., OUT-side this time) right thereafter. After being recorded in the image processing and recording device 120, the image data thereof is compared to the image data at the same portion recorded in the image processing and recording device 121 at the arithmetic device 130. When an imperfection exists, the imperfect portion thereof is recorded in the imperfect portion recording device 140 (step 207) and the glass substrate 1 stops (step 208). Subsequently, processes of the leftward processing (for lines of N=3, 5, 7, . . . ) and the return processing (for lines of N+1=4, 6, 8, . . . ) are repeated until the final line is formed (steps 202 to 210). After processing of the predetermined number of lines set by a program is determined as being completed is step 205 or step 209, the number of imperfections such as discontinuation or swell of the scribe lines and the imperfect positions thereof are displayed on an operational monitor (step 211). Based on automatic comparison with a threshold value of the number of imperfections previously set in an inspection program, instructions of categorization for ranking, no-processing, repair-processing or the like for the substrate having the final scribe line formed are displayed on the operational monitor (step 212). Then, it is determined whether or not the repair processing is performed (step 213). If required (i.e., in the case of “Yes”), a scribe line to bypass the position of the glass scratch 9, the adhered foreign matter 10 or the like is formed (step 214) and the operation ends.

Here, in step 203 or step 207, an example to compare the image data of the inspection cameras of the IN-side to the image data of the OUT-side is described. However, if the image of the OUT-side is sufficiently clear, it is also possible to determine the imperfect portions only by the images of the OUT-side.

### APPARATUS EXAMPLE 2

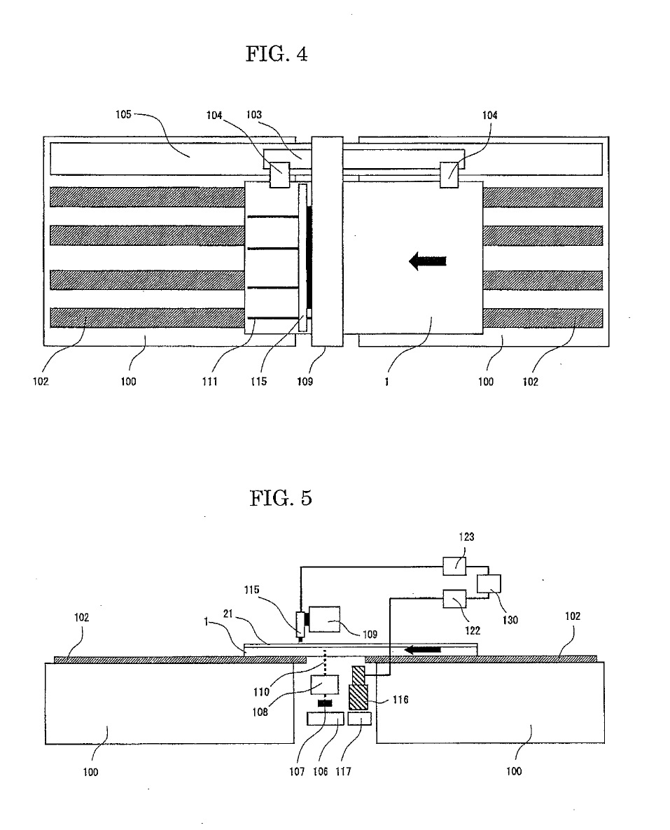

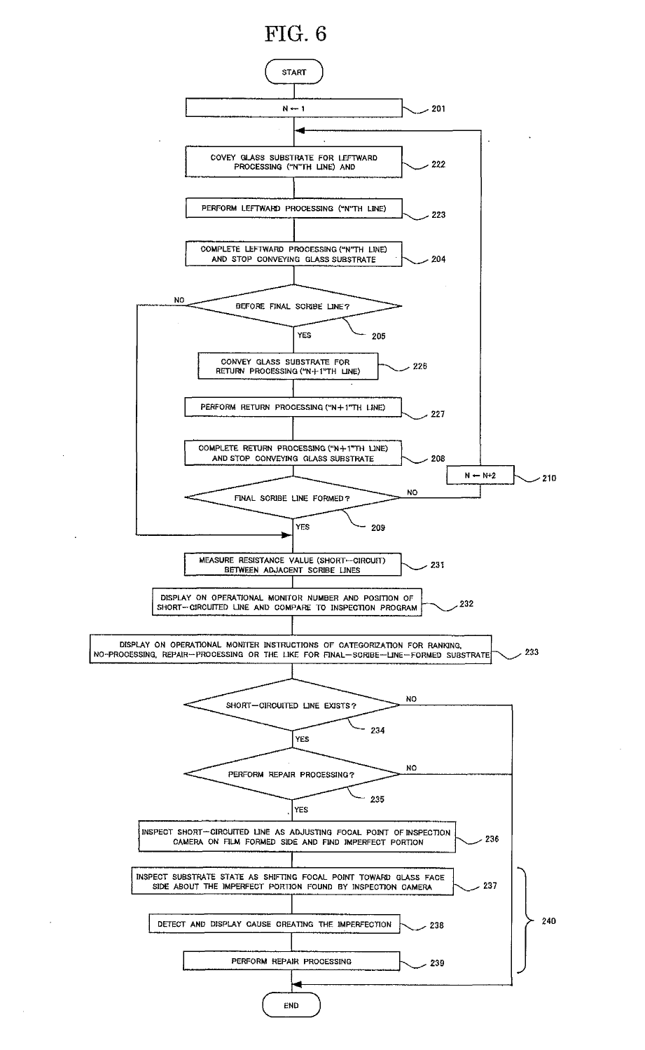

FIGS. 4 and 5 illustrate a laser scribing apparatus preferable for a laser describing method according to apparatus example 2 of the present invention. FIG. 4 is a plan view and FIG. 5 is a front view. The same numeral is given to the similar element of an apparatus in the related art in FIGS. 12 and 13 and description thereof will not be repeated.

A laser scribing apparatus of apparatus example 2 of the present invention is provided with a resistance tester 115 between adjacent solar cell units facing the film formed side of the glass substrate 1 and the inspection camera by one side of the processing head facing the glass face side of the glass substrate. One or more inspection cameras 116 are fixed on the camera table 117 movable in the same direction as the movable table 106 (i.e., the direction perpendicular to the scribe lines 111). Resistance values between the adjacent scribe lines can be measured by the resistance tester 115 and the image of substrate surface after the final scribe line is formed can be captured by the inspection cameras 116. The inspection cameras 116 are each provided with an epi-illumination device (not illustrated) of a coaxial type or an oblique type such as ring-shaped illumination.

The operation of the laser scribing apparatus of apparatus example 2 of the present invention will be described with reference to a flowchart of FIG. 6. Steps 201 to 210 are approximately similar to those in the flowchart of the related art described in FIG. 14. The glass substrate 1 having a film-formed layer 21 is conveyed and supplied to the conveying surface 102. In this processing apparatus, the dust collector 109 is arranged right above a position of the glass substrate 1 irradiated with laser light through a condenser lens 108 so as to be configured to be capable of removing powder dust and the like generated by the laser processing. The glass substrate 1 supplied on the conveying surface 102 is chucked by the glass substrate hold portion 104 so as to be in a state of being capable of reciprocating on the conveying surface 102. When the processing is started with an operator's instruction or the like, the movable table 106 having the processing head mounted is moved to a position for the first scribe line and N is set to be one as the first line (step 201). The glass substrate 1 is conveyed for leftward processing (step 222) and the leftward processing (for the first line) is performed as the glass substrate 1 passes above the laser light irradiation position at a predetermined set speed (step 223). After the first scribe line is formed with the leftward processing, the glass substrate 1 stops moving on the conveying surface 102 and the movable table 106 is moved to the position for the next scribe line (step 204). Here, after checking whether or not being the final scribe line (step 205), the glass substrate 1 is conveyed for return processing (step 226). The return processing (for the second line as being N+1) is performed as the glass substrate 1 passes above the laser light irradiation position at the predetermined set speed (step 227) and the glass substrate 1 stops (step 208). Subsequently, processes of the leftward processing (for lines of N=3, 5, 7, . . . ) and the return processing (for lines of N+1=4, 6, 8, . . . ) are repeated until the final line is formed (steps 222 to 210). The operation ends when processing of the predetermined number of lines set by a program is completed.

After the final scribe line is formed, the resistance values between adjacent scribe lines are measured with the resistance tester 115 disposed facing the film face side of the glass substrate 1, so that presence or absence of short-circuit is detected (step 231). The measured data is recorded at a recording device 123. After obtaining the result of the resistance value measurement, the operational monitor displays presence or absence of a short-circuited line (i.e., an imperfect line) and the number and positions of short-circuited lines in the case of presence (step 232). Based on automatic comparison with a threshold value of the number of imperfections previously set in an inspection program, instructions of categorization for ranking, no-processing, repair-processing or the like for the substrate having the final scribe line formed are displayed on the operational monitor (step 233). Then, it is determined whether or not a short-circuited line exists (step 234). The operation ends when a short-circuited line does not exist.

When a short-circuited line exists (in the case of “Yes”), it is determined whether or not the repair processing is performed if necessary (step 235). In the case of performing, proceeding to a repair processing step 240 consists of the following three steps, the position information of the short-circuited line detected by the resistance tester 115 recorded in the recording device 123 is transmitted via the arithmetic device 130 to a drive portion of the movable table 117 to which the inspection cameras 116 are mounted. The inspection camera 116 is moved to the position of the short-circuited line based on the position information from the arithmetic device 130. First, the inspection camera 116 is focused on the scribe line formed on the film formed side, that is, formed in the corresponding layer and the short-circuited line image is captured as conveying and moving the glass substrate 1, so that the imperfect portion is found based on the image information recorded in the image processing and recording device 122 (step 236). Next, when images are captured at the found imperfect portion as the focal point of the inspection camera 116 is shifted from the film formed side to the glass face side, the focal point is to be matched to a cause creating the imperfection such as a glass scratch 9, a adhered foreign matter 10, an air-bubble 15, or the like. In this manner, the cause is detected (step 237). Then, the position, size, shape and the like thereof are recorded in the image processing and recording device 122 and the detecting operation ends. At that time, the focal point, which is at the focal length 20 from the camera, is to be adjusted by automatically moving the inspection camera 116 in the vertical direction (upward and downward) against the glass substrate (as illustrated as A to D in FIG. 17). Then, the imperfect portion is displayed on the operational monitor (step 238). The repair processing is performed with the same apparatus to form a new scribe line to bypass the position of the glass scratch 9, the adhered foreign matter 10, the air-bubble, or the like based on the information from the image processing and recording device 122 (step 239) and the operation ends. By utilizing the present repair step 240, the size of the air-bubble 15 in the glass substrate can be measured as well as the size of the glass scratch 9 or the adhered foreign matter 10 on the glass substrate surface.

### PROCESSING EXAMPLE 1

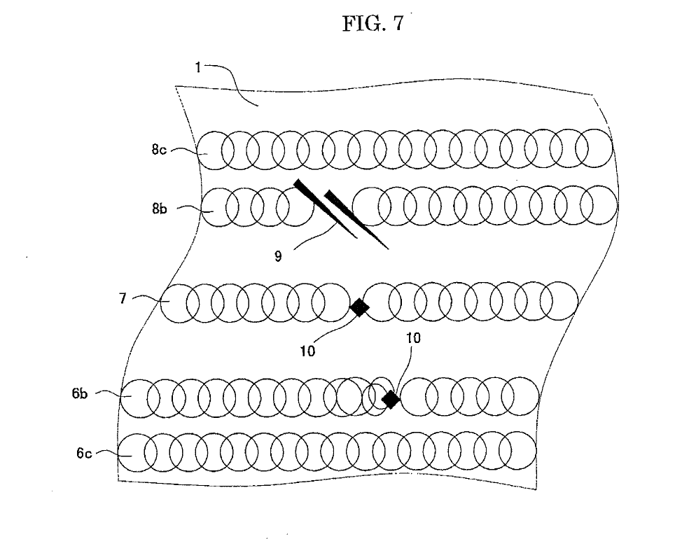

FIG. 7 is an example of the first repair processing with the laser scribing according to the present invention. For a scribe line 8b having an imperfect portion 9, an appropriate distance between a repair line and the scribe line 8b is determined by the accurate position, size, shape and the like of the imperfect portion 9 recorded in the imperfect portion recording device 140 or the image processing and recording device 122. Then, a linear scribe line 8c for repairing is newly formed at a position shifted by the determined distance from the imperfect portion 9. For a scribe line 6b having an imperfect portion 10, an appropriate distance between a repair line and the scribe line 6b is determined by the accurate position, size, shape and the like of the imperfect portion 10 recorded in the imperfect portion recording device 140 or the image processing and recording device 122. Then, a linear scribe line 6c for repairing is newly formed at a position shifted by the determined distance from the imperfect portion 10. Here, in order to avoid overlapping with the scribe line 7, the bypass (repair) scribe lines 8c, 6c are preferably formed each near the side of the corresponding scribe line opposite to the scribe line 7. The repair processing of the present example only forms a new linear scribe line as being easily controlled. Accordingly, since the operation of moving and stopping of the glass substrate to the repair processing position is not required, repair processing time can be shortened in the case that a plural repair lines are necessary on the same line. However, in the present example, effective photovoltaic area of the amorphous silicon layer is decreased a little.

### PROCESSING EXAMPLE 2

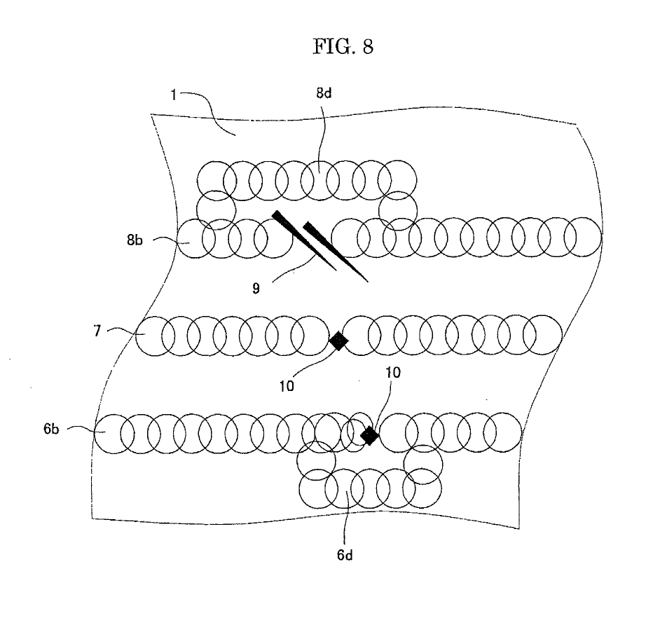

FIG. 8 is an example of the second repair processing with the laser scribing according to the present invention. For the scribe line 8b having an imperfect portion 9, a length of a repair line 8d and a distance between the repair line 8d and the scribe line 8b are appropriately determined by the accurate position, size, shape and the like of the imperfect portion 9 recorded in the imperfect portion recording device 140 or the image processing and recording device 122. Then, the rectangular scribe line 8d for repairing is formed to bypass the imperfect portion 9. For the scribe line 6b having an imperfect portion 10, a length of a repair line 6d and a distance between the repair line 6d and the scribe line 6b are appropriately determined by the accurate position, size, shape and the like of the imperfect portion 10 recorded in the imperfect portion recording device 140 or the image processing and recording device 122. Then, the rectangular scribe line 6d for repairing is formed to bypass the imperfect portion 10. Here, in order to avoid overlapping with the scribe line 7, the bypass scribe lines 8d, 6d are preferably formed each near the side of the corresponding scribe line opposite to the scribe line 7. The repair processing of the present example only forms a rectangular scribe line to bypass the imperfect portion. Accordingly, the repair processing time can be shortened, and the decrease in photovoltaic efficiency can be suppressed to the minimum because the present example causes little decrease in effective photovoltaic area of the amorphous silicon layer.

### PROCESSING EXAMPLE 3

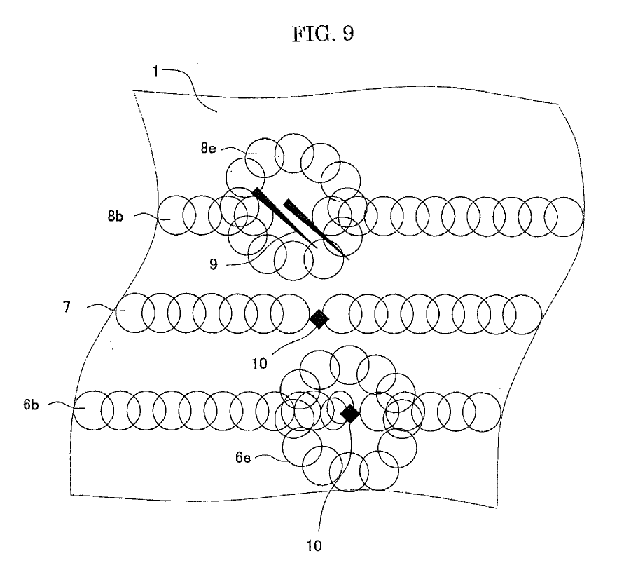

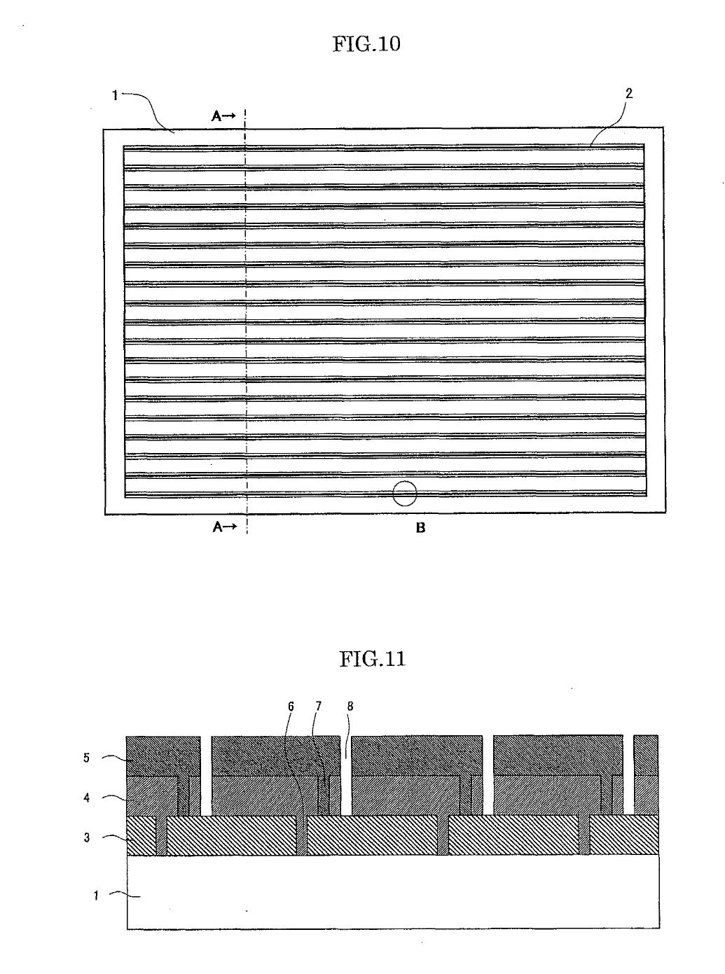

FIG. 9 is an example of the third repair processing with laser scribing according to the present invention. For the scribe line 8b having an imperfect portion 9, an appropriate diameter of a repair line 8e is determined by the accurate position, size, shape and the like of the imperfect portion 9 recorded in the imperfect portion recording device 140 or the image processing and recording device 122. Then, the circular scribe line 8e is formed for repairing so that the imperfect portion 9 is to be the center thereof. For the scribe line 6b having an imperfect portion 10, an appropriate diameter of a repair line is determined by the accurate position, size, shape and the like of the imperfect portion 10 recorded in the imperfect portion recording device 140 or the image processing and recording device 122. Then, the circular scribe line 6e is formed for repairing so that the imperfect portion 10 is to be the center thereof. In the present example, the circular scribe line 8e being centered on the imperfect portion 9 overlaps with the imperfect portion 9 in the lower side of the circle, for example. However, since the scribe line is only required to be connected through either side of the circle, there is no problem in this case due to connection in the upper side. Here, in order to avoid overlapping with the scribe line 7, the circular scribe lines 8e, 6e are each required to have a radius being smaller than the distance between the corresponding scribe line and the scribe line 7 when the center of the trepanning circle is set on the scribe line. Meanwhile, when the center of the trepanning circle is not set on the scribe line, the diameter is only required to avoid overlapping with the scribe line 7. Since the repair processing of the present example may employ trepanning which is an often used control method of a pair of galvanometer mirrors being as the reflection mirrors 107, the decrease in photovoltaic efficiency can be suppressed to the minimum as being easily controlled. The present example also causes little decrease in effective photovoltaic area of the amorphous silicon layer 4.

Here, in apparatus example 1 illustrated in FIGS. 1 and 2, by further disposing the image processing and recording device 122, one or more inspection cameras 116 and the movable table 117, and replacing step 214 in FIG. 3 with step 240 in FIG. 6, it also becomes possible to perform repairing as measuring the size of the air-bubble 15 in the glass substrate.
FIG. 3
START
202 CONVEY GLASS SUBSTRATE FOR LEFTWARD PROCESSING (“N”TH LINE) AND CAPTURE SUBSTRATE SURFACE IMAGE WITH INSPECTION CAMERA ABOVE GLASS SUBSTRATE IN-SIDE
203 PERFORM LEFTWARD PROCESSING (“N”TH LINE) AND CAPTURE SCRIBE LINE IMAGE WITH INSPECTION CAMERA ABOVE GLASS SUBSTRATE OUT-SIDE
204 COMPLETE LEFTWARD PROCESSING (“N”TH LINE) AND STOP CONVEYING GLASS SUBSTRATE
205 BEFORE FINAL SCRIBE LINE?
206 CONVEY GLASS SUBSTRATE FOR RETURN PROCESSING (“N+1”TH LINE) AND CAPTURE SUBSTRATE SURFACE IMAGE WITH INSPECTION CAMERA ABOVE GLASS SUBSTRATE IN-SIDE
207 PERFORM RETURN PROCESSING (“N+1”TH LINE) AND CAPTURE SCRIBE LINE IMAGE WITH INSPECTION CAMERA ABOVE GLASS SUBSTRATE OUT-SIDE
208 COMPLETE RETURN PROCESSING (“N+1”TH LINE) AND STOP CONVEYING GLASS SUBSTRATE
209 FINAL SCRIBE LINE FORMED?
211 DISPLAY ON OPERATIONAL MONITOR NUMBER AND POSITION OF IMPERFECTION AND COMPARE TO INSPECTION PROGRAM
212 DISPLAY ON OPERATIONAL MONITOR INSTRUCTIONS OF CATEGORIZATION FOR RANKING, NO-PROCESSING, REPAIR-PROCESSING OR THE LIKE FOR FINAL-SCRIBE-LINE-FORMED SUBSTRATE
213 PERFORM REPAIR PROCESSING?
214 PERFORM REPAIR PROCESSING
END
FIG. 6
START
222 CONVEY GLASS SUBSTRATE FOR LEFTWARD PROCESSING (“N”TH LINE)
223 PERFORM LEFTWARD PROCESSING (“N”TH LINE)
204 COMPLETE LEFTWARD PROCESSING (“N”TH LINE) AND STOP CONVEYING GLASS SUBSTRATE
205 BEFORE FINAL SCRIBE LINE?
226 CONVEY GLASS SUBSTRATE FOR RETURN PROCESSING (“N+1”TH LINE)
227 PERFORM RETURN PROCESSING (“N+1”TH LINE)
208 COMPLETE RETURN PROCESSING (“N+1”TH LINE) AND STOP CONVEYING GLASS SUBSTRATE
209 FINAL SCRIBE LINE FORMED?
231 MEASURE RESISTANCE VALUE (SHORT-CIRCUIT) BETWEEN ADJACENT SCRIBE LINES
232 DISPLAY ON OPERATIONAL MONITOR NUMBER AND POSITION OF SHORT-CIRCUITED LINE AND COMPARE TO INSPECTION PROGRAM
233 DISPLAY ON OPERATIONAL MONITOR INSTRUCTIONS OF CATEGORIZATION FOR RANKING, NO-PROCESSING, REPAIR-PROCESSING OR THE LIKE FOR FINAL-SCRIBE-LINE-FORMED SUBSTRATE
234 SHORT-CIRCUITED LINE EXISTS?
235 PERFORM REPAIR PROCESSING?
236 INSPECT SHORT-CIRCUITED LINE AS ADJUSTING FOCAL POINT OF INSPECTION CAMERA ON FILM FORMED SIDE AND FIND IMPERFECT PORTION
237 INSPECT SUBSTRATE STATE AS SHIFTING FOCAL POINT TOWARD GLASS FACE SIDE ABOUT THE IMPERFECT PORTION FOUND BY INSPECTION CAMERA
238 DETECT AND DISPLAY CAUSE CREATING THE IMPERFECTION
239 PERFORM REPAIR PROCESSING
END
FIG. 14
START
302 CONVEY GLASS SUBSTRATE FOR LEFTWARD PROCESSING (“N”TH LINE)
303 PERFORM LEFTWARD PROCESSING (“N”TH LINE)
304 COMPLETE LEFTWARD PROCESSING (“N”TH LINE) AND STOP CONVEYING GLASS SUBSTRATE
305 BEFORE FINAL SCRIBE LINE?
306 CONVEY GLASS SUBSTRATE FOR RETURN PROCESSING (“N+1”TH LINE)
307 PERFORM RETURN PROCESSING (“N+1”TH LINE)
308 COMPLETE RETURN PROCESSING (“N+1”TH LINE) AND STOP CONVEYING GLASS SUBSTRATE
309 FINAL SCRIBE LINE FORMED?
END

What is claimed is:

1. A method of manufacturing a thin-film solar panel with a laser scribing process to perform linear groove processing by irradiating a thin-film layer formed on a substrate with laser light to be separated from adjacent structure, comprising steps of:
specifying a position and a size of a cause creating an imperfection by inspecting a scribe line; and
performing repair processing to form a new scribe line to bypass the portion of the imperfection after a final scribe line is formed.

2. The method of manufacturing a thin-film solar panel according to claim 1, wherein the new scribe line to bypass the imperfect portion is shaped linear.

3. The method of manufacturing a thin-film solar panel according to claim 1, wherein the new scribe line to bypass the imperfect portion is shaped rectangular.

4. The method of manufacturing a thin-film solar panel according to claim 1, wherein the new scribe line to bypass the imperfect portion is shaped circular.

5. The method of manufacturing a thin-film solar panel according to claim 1, comprising the step of specifying a position and a size of a cause creating the imperfection by comparing images of before and after processing captured with inspection cameras disposed respectively right before and right after a processing head for the laser scribing.

6. The method of manufacturing a thin-film solar panel according to claim 1, comprising the step of specifying a position and a size of a cause creating the imperfection by detecting a short-circuited line by measuring resistance values between adjacent scribe lines with a resistance tester disposed facing a film formed side of a glass substrate after the final scribe line is formed and by capturing an image of the short-circuited line which requires repair processing with an inspection camera disposed facing a glass face side of the glass substrate.

7. The method of manufacturing a thin-film solar panel according to claim 6, comprising the step of specifying a size of an air-bubble in the glass substrate by vertically shifting the focal point of the inspection camera disposed facing the glass face side.

8. A laser scribing apparatus which is used for laser scribing processing of a thin-film solar panel to perform linear groove processing by irradiating a thin-film layer formed on a substrate with laser light to be separated from adjacent structure, comprising:
one or more inspection cameras disposed right after a processing head to specify a cause creating an imperfection as inspecting a scribe line; and
a recording device to record a position and the like of the imperfect portion;
wherein repair processing to form a new scribe line bypassing the recorded imperfect portion is performed after a final scribe line is formed.

9. The laser scribing apparatus according to claim 8,
wherein two or more inspection cameras are disposed respectively right before and right after the processing head to capture surface images of the glass substrate; and the imperfect portion is specified by comparison of the captured images.

10. A laser scribing apparatus which is used for laser scribing of a thin-film solar panel to perform linear groove processing by irradiating a thin-film layer formed on a substrate with laser light to be separated from adjacent structure, comprising:
a resistance tester disposed facing a film formed side of a glass substrate to detect a short-circuited line by measuring resistance values between adjacent scribe lines;
one or more inspection cameras disposed facing a glass face side of the glass substrate including a mechanism portion to adjust focal point for specifying a cause creating a scribe line imperfection; and
an image processing and recording device to record a position and the like of the imperfect portion;
wherein repair processing to form a new scribe line bypassing the recorded imperfect portion is performed after a final scribe line is formed.
